(19) United States
(12) Patent Application Publication
(10) Pub. No.: US 2004/0205437 A1
(43) Pub. Date: Oct. 14, 2004

(54) System for testing device under test and test method thereof

(76) Inventors: Sung-Po Yao, Kaohsiung City (TW); Yueh-Lung Lin, Lujhu Township (TW); Yi-Lung Lin, Kaohsiung City (TW); Ho-Ming Tong, Taipei City (TW); Chun-Chi Lee, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/800,823

(22) Filed: Mar. 15, 2004

(30) Foreign Application Priority Data
Mar. 17, 2003 (TW) 092105838

(51) Int. Cl. G01R 31/28; G06F 11/00

(52) U.S. Cl. 714/742

(57) ABSTRACT

A test system for testing a device under test (DUT) and a test method thereof. At first, an expected test pattern having a test input signal and an expected output signal is output. Next, the expected test pattern is compressed, and an expected compressed pattern having an expected compressed output signal corresponding to the expected output signal is output and saved. Then, the expected compressed pattern is decompressed, and the test input signal is applied to the DUT for testing the DUT. Next, a real output signal output from the DUT is received and compressed, and then a real compressed output signal is output and saved. At last, the real compressed output signal and the expected compressed output signal are compared to determine the test result.

This application claims the benefit of Taiwan application Serial No. 092105838, filed Mar. 17, 2003, the subject matter of which is incorporated herein by reference.

### BACKGROUND OF THE INVENTION

1. Field of the Invention

The invention relates to a test system for testing a device under test and a test method thereof, and more particularly to a test system for testing a device under test and a test method thereof capable of compressing output and input results of an expected test pattern generated from an automatic test pattern generator (ATPG) so as to reduce the dimension of the expected test pattern.

2. Description of the Related Art

In the current age of rapidly developed technology, electrical apparatuses have become important tools in the daily life of the modern human beings. The electrical apparatuses need to incorporate semiconductor devices so that they can operate normally. Thus, the designs of the semiconductor devices are quite important. The volumes of the semiconductor devices are correspondingly reduced and the digital circuits of the semiconductor devices are correspondingly complicated because the modern human beings may search for miniaturized electrical apparatuses. Although the digital circuits of the semiconductor devices are very complicated, electronic design automation is typically employed in the industry to help the engineers to design the required digital circuits of the semiconductor devices, thereby simplifying the designs of the semiconductor devices. In the electronic design automation, the manufacturers may often utilize a scan-test flow for a design for test (DFT) in a test system for testing semiconductor devices and determining whether the semiconductor devices are passed or failed.

FIG. 1 is a block diagram showing a conventional test system for testing a device under test (DUT) 100. Referring to FIG. 1, the test system for testing a DUT 100 includes an automatic test pattern generator (ATPG) 102, an automatic test equipment (ATE) 104, and a loadboard 108. The DUT may be an integrated circuit device such as a semiconductor device or chip. The ATPG 102 has an expected test pattern corresponding to the DUT. The expected test pattern has a test input signal and an expected output signal, which is a result that should be generated after the DUT receives the test input signal and the DUT is tested under a normal condition.

The ATE 104 has a memory 106 coupled to the ATPG 102 for receiving and saving the expected test pattern. The loadboard 108 is coupled to the memory 106 and the DUT is placed on the loadboard 108. The loadboard 108 acquires the test input signal saved in the memory 106 and outputs the test input signal to the DUT. The loadboard 108 receives a real output signal output from the DUT and outputs the real output signal to the memory 106 for saving the real output signal. The ATE 104 judges whether the DUT is passed or failed according to the real output signal and the expected output signal. If the real output signal is the same as the expected output signal, it is judged that the DUT is passed. If the real output signal is different from the expected output signal, it is judged that the DUT is failed.

FIG. 2 is a flow chart showing a test method in the test system for testing the DUT 100 of FIG. 1. Please refer to FIGS. 1 and 2 simultaneously. At first, in step 202, the ATPG 102 generates an expected test pattern corresponding to the DUT and outputs the expected test pattern. Next, in step 204, the memory 106 receives and saves the expected test pattern. Then, in step 206, when the DUT is placed on the loadboard 108, the loadboard 108 acquires the test input signal saved in the memory 106 and outputs the test input signal to the DUT. Next, in step 208, the loadboard 108 receives a real output signal output from the DUT and outputs the real output signal to the memory 106, which saves the real output signal. Then, in step 210, the ATE 104 judges whether or not the real output signal and the expected output signal are the same. If the real output signal and the expected output signal are the same, the process goes to step 212, in which the ATE 104 judges that the DUT is passed and the method is ended. If the real output signal and the expected output signal are different, the process goes to step 214, in which the ATE 104 judges that the DUT is failed and the method is ended.

With the increase of the functions of the DUT, the design of the digital circuit of the DUT becomes more complicated, and the dimension of the automatic test pattern, which is generated from the ATPG 102 and corresponds to the DUT, is enlarged correspondingly. Therefore, the storage capacity of the ATE 104 has to be expanded correspondingly so as to save the automatic test pattern. Since the dimension of the automatic test pattern is getting larger and larger, the manufacturer has to spend a lot of money to purchase the expensive memory every period of time in order to increase the storage capacity of the ATE 104. Consequently, the test cost is increased, and the economic efficiency cannot be met.

### SUMMARY OF THE INVENTION

It is therefore an objective of the invention to provide a test system for testing a device under test and a test method thereof capable of greatly reducing the dimension of the expected test pattern by compressing and then saving the expected test pattern. Thus, it is possible to avoid the problem of changing the memory of the test equipment owing to the oversized expected test pattern, and the test cost may be reduced.

The invention achieves the above-identified objective by providing a test system for testing a device under test (DUT). The test system includes an automatic test pattern generator, a compressor, an automatic test equipment, and compressing/decompressing unit. The automatic test pattern generator generates an expected test pattern corresponding to the DUT and then outputs the expected test pattern. The expected test pattern has a test input signal and an expected output signal. The compressor receives and compresses the expected test pattern and then outputs an expected compressed pattern, which has an expected compressed output signal corresponding to the expected output signal. The automatic test equipment saves the expected compressed pattern and a real compressed output signal and compares the real compressed output signal to the expected compressed output signal. The compressing/decompressing unit acquires and then decompresses the expected compressed pattern of the automatic test equipment so as to test the DUT using the test input signal and then to output a real output signal. The compressing/decompressing unit further compresses the real output signal into the real compressed output signal.

The invention also achieves the above-identified objective by providing a test method for testing a device under test (DUT). In this method, an expected test pattern, which corresponds to the DUT and has a test input signal and an expected output signal, is output at first. Next, the expected test pattern is compressed, and an expected compressed pattern having an expected compressed output signal corresponding to the expected output signal is output accordingly. Then, the expected compressed pattern is saved. Next, the expected compressed pattern is acquired and decompressed, and the DUT is tested using the output test input signal. Then, a real output signal output from the DUT is received and compressed, and a real compressed output signal is output. Next, the real compressed output signal is saved, and it is judged that whether or not the real compressed output signal and the expected compressed output signal are the same.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a block diagram showing a conventional test system for testing a device under test.

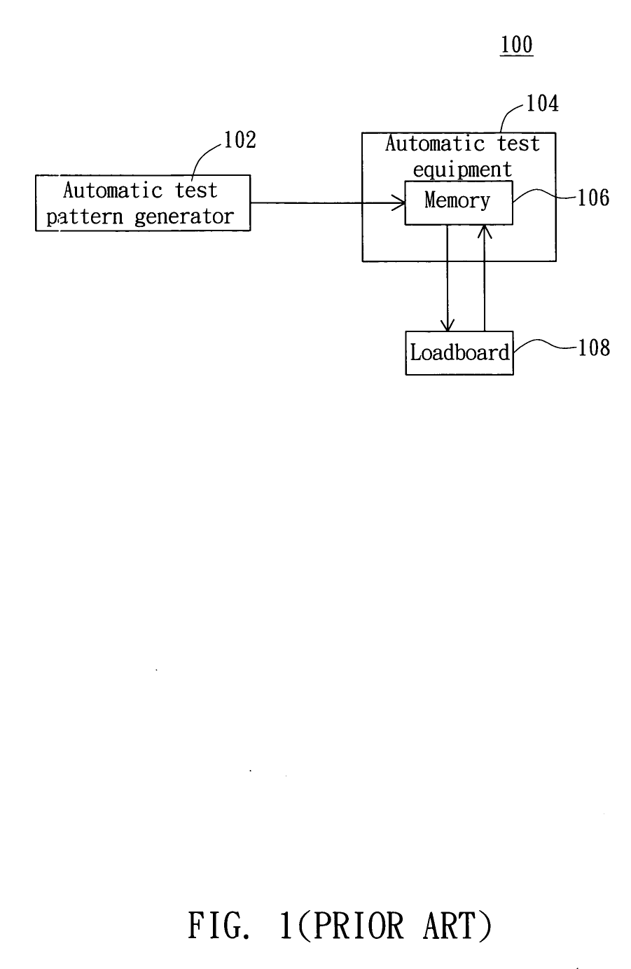

FIG. 2 is a flow chart showing a test method in the test system for testing the DUT of FIG. 1.

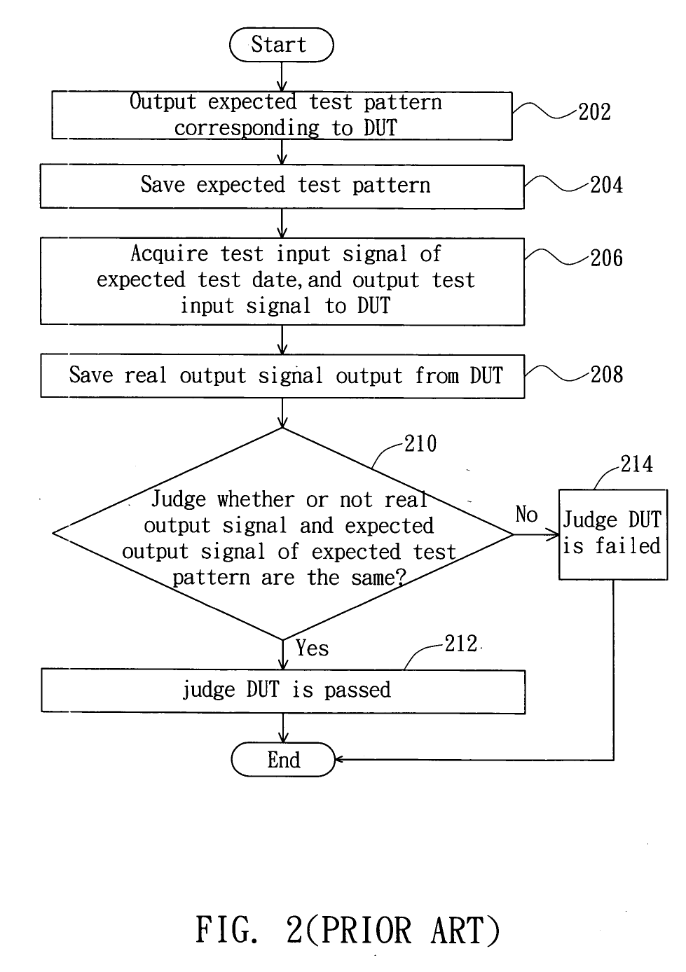

FIG. 3 is a block diagram showing a test system for testing a device under test according to a preferred embodiment of the invention.

FIG. 4 is a flow chart showing a test method in the test system for testing the DUT of FIG. 3.

### DETAILED DESCRIPTION OF THE INVENTION

The invention particularly designs a test system for testing a device under test and a test method thereof capable of greatly reducing the dimension of the expected test pattern by compressing and then saving the expected test pattern. Therefore, it is possible to avoid the problem of changing the insufficient memory of the test equipment owing to the oversized expected test pattern required by the complicated DUT, and the test cost may be reduced.

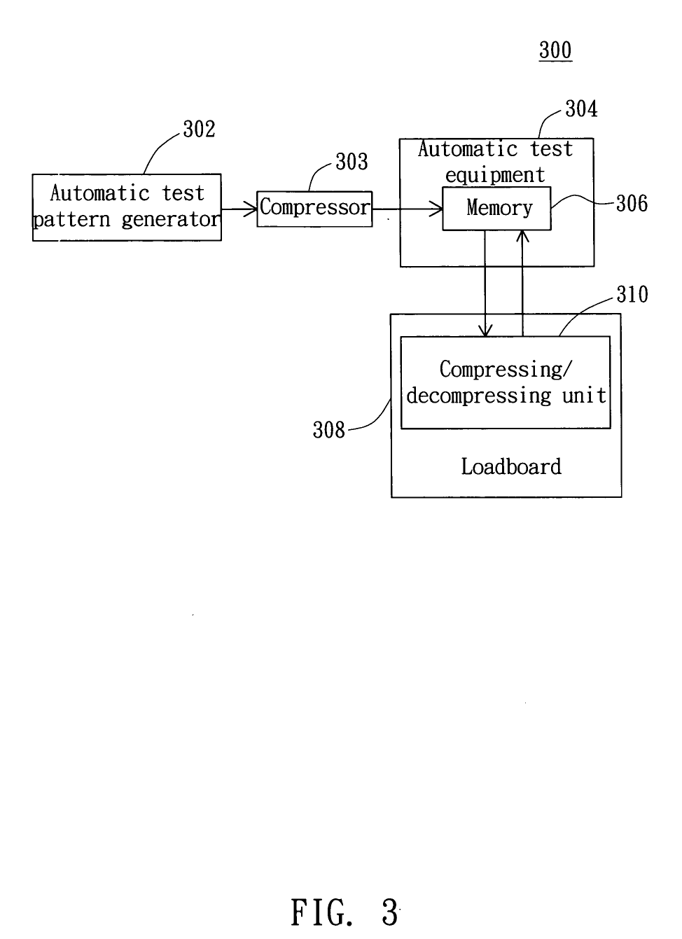

FIG. 3 is a block diagram showing a test system for testing a device under test (DUT) 300 according to a preferred embodiment of the invention. Referring to FIG. 3, the test system for testing the DUT 300 includes an automatic test pattern generator (ATPG) 302, a compressor 303, an automatic test equipment (ATE) 304, and a loadboard 308. The compressor 303 is coupled to the ATPG 302 and ATE 304, and the loadboard 308 is coupled to the ATE 304. The ATPG 302 generates an expected test pattern corresponding to the DUT and decompresses the expected test pattern. In this embodiment, the pattern may be a scan test pattern. The decompressed expected test pattern includes a test input signal and an expected output signal, which is a result that should be generated after the DUT receives the test input signal and the DUT is tested under a normal condition. The compressor 303 receives the expected test pattern of the ATPG 302, compresses the expected test pattern using a compressing algorithm, and then outputs an expected compressed test pattern. The expected compressed pattern has a tested compressed input signal corresponding to the test input signal and an expected compressed output signal corresponding to the expected output signal.

The ATE 304 has a memory 306 for saving the expected compressed test pattern of the compressor 303. The loadboard 308, on which the DUT is placed, tests the DUT. The loadboard 308 has a compressing/decompressing unit 310, which may be a chip. When the DUT is placed on the loadboard 308, the compressing/decompressing unit 310 acquires the expected compressed test pattern of the memory 306, decompresses the expected compressed test pattern, and outputs the test input signal to the loadboard 308 in order to test the DUT. The compressing/decompressing unit 310 receives and then compresses a real output signal output from the DUT, and then outputs a real compressed output signal to the memory 306, which saves the real compressed output signal. The ATE 304 judges whether or not the DUT is passed according to the real compressed output signal and the expected compressed output signal. If the real compressed output signal and the expected compressed output signal are the same, the DUT is passed. If the real compressed output signal and the expected compressed output signal are different, the DUT is failed.

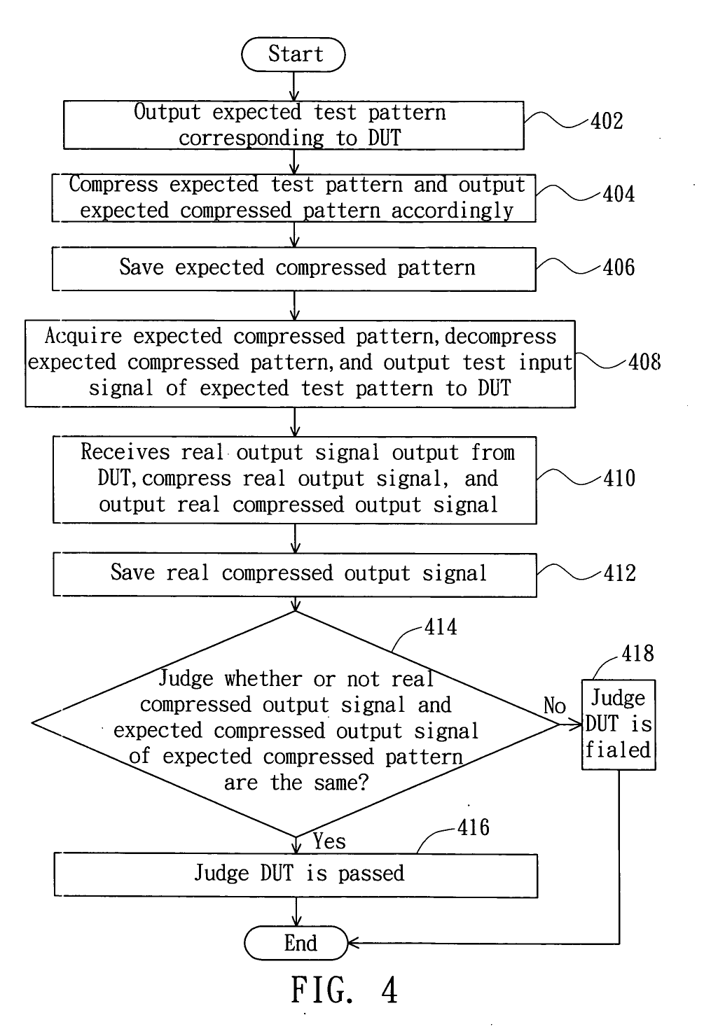

FIG. 4 is a flow chart showing a test method in the test system for testing the DUT 300 of FIG. 3. Please refer to FIGS. 3 and 4 simultaneously. At first, in step 402, the ATPG 302 generates and then outputs an expected test pattern corresponding to the DUT, wherein the expected test pattern has a test input signal and an expected output signal. Next, in step 404, the compressor 303 receives and compresses the expected test pattern, and then outputs an expected compressed pattern having a tested compressed input signal corresponding to the test input signal and an expected compressed output signal corresponding to the expected output signal. The magnitudes of the tested compressed input signal and the expected compressed output signal are smaller than those of the test input signal and the expected output signal, respectively. Then, in step 406, the memory 306 receives and saves the expected compressed pattern. Next, in step 408, the compressing/decompressing unit 310 acquires and decompresses the expected compressed pattern of the memory 306, and then outputs the test input signal of the expected test pattern to the loadboard 308 for testing the DUT. Then, in step 410, the compressing/decompressing unit 310 receives a real output signal output from the loadboard 308 after the DUT is tested, compresses the real output signal, and then outputs a real compressed output signal. Next, in step 412, the memory 306 receives and saves the real compressed output signal. Then, in step 414, the ATE 304 judges that whether or not the expected compressed output signal and the real compressed output signal are the same. If the expected compressed output signal and the real compressed output signal are the same, as shown in step 416, the ATE 304 judges that the DUT is passed and the method is ended. If the expected compressed output signal and the real compressed output signal are different, as shown in step 418, the ATE 304 judges that the DUT is failed and the method is ended.

In addition, the method compresses the expected test pattern into an expected compressed pattern using a compressing algorithm, and decompresses the expected compressed pattern into an expected test pattern using a decompressing algorithm. The compressing algorithm also may be used in this method to compress the real output signal into a real compressed output signal.

It is to be noted that the expected test pattern, which is decompressed and output by the compressing/decompressing unit 310, has to be the same as the expected test pattern generated by the ATPG 302. In addition, in order to perform the comparison, the format of the expected compressed output signal of the expected compressed pattern, which is compressed and output by the compressor 303 has to be the same as that of the real compressed output signal, which is compressed and output by the compressing/decompressing unit 310.

One of ordinary skill in the art may easily understand that the invention is not limited thereto. For instance, the compressor 303 and the compressing/decompressing unit 310 may be combined into a compressing/decompressing apparatus. Also, the compressor 303 and the compressing/decompressing unit 310 may be disposed in the ATE 304. In addition, the compressing/decompressing unit 310 may be a chip having the compressing/decompressing algorithm.

The test system for testing a device under test and a test method thereof of the invention are capable of greatly reducing the dimension of the expected test pattern by compressing and then saving the expected test pattern. Therefore, it is possible to avoid the problem of changing the insufficient memory every period of time owing to the enlarging expected test pattern required by the complicated DUT, and the test cost may be saved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A test method for testing a device under test (DUT), the method comprising the steps of:
outputting an expected test pattern corresponding to the DUT, the expected test pattern having a test input signal and an expected output signal;
compressing the expected test pattern and outputting an expected compressed pattern having an expected compressed output signal corresponding to the expected output signal;
saving the expected compressed pattern;
acquiring and decompressing the expected compressed pattern, and then outputting the test input signal to test the DUT;
receiving and compressing a real output signal output from the DUT, and then outputting a real compressed output signal;
saving the real compressed output signal; and
judging whether or not the real compressed output signal and the expected compressed output signal are the same.

2. The test method according to claim 1, wherein the output expected test pattern is a scan test pattern.

3. The test method according to claim 1, wherein the method is applied to a test system comprising:
an automatic test pattern generator (ATPG) for generating and outputting the expected test pattern.

4. The test method according to claim 3, wherein the test system further comprises:
a compressor for receiving and compressing the expected test pattern, and then outputting the expected compressed pattern.

5. The test method according to claim 4, wherein the test system further comprises:
an automatic test equipment (ATE) including a memory for saving the expected compressed pattern and the real compressed output signal, the ATE judging whether or not the real compressed output signal and the expected compressed output signal are the same.

6. The test method according to claim 5, wherein the test system further comprises:
a loadboard on which the DUT is placed, the loadboard having a compressing/decompressing unit for acquiring and decompressing the expected compressed pattern, outputting the test input signal to test the DUT, compressing the real output signal, which is output after the DUT is tested, into the real compressed output signal, and saving the real compressed output signal into the memory.

7. The test method according to claim 1, wherein:
when the real compressed output signal and the expected compressed output signal are the same, it is judged that the DUT is passed; and
when the real compressed output signal and the expected compressed output signal are different, it is judged that the device under test is failed.

8. A test system for testing a device under test (DUT), the system comprising:
an automatic test pattern generator for generating and outputting an expected test pattern corresponding to the DUT, the expected test pattern having a test input signal and an expected output signal.
a compressor for receiving and compressing the expected test pattern, and then outputting an expected compressed pattern having an expected compressed output signal corresponding to the expected output signal;
an automatic test equipment for saving the expected compressed pattern and a real compressed output signal, and comparing the real compressed output signal to the expected compressed output signal; and
a compressing/decompressing unit for acquiring and decompressing the expected compressed pattern of the automatic test equipment, testing the DUT using the test input signal, outputting a real output signal, and compressing the real output signal into the real compressed output signal.

9. The test system according to claim 8, wherein the automatic test equipment comprises:
a memory for saving the expected compressed pattern and the real compressed output signal.

10. The test system according to claim 8, further comprising:
a loadboard on which the DUT is placed, the loadboard having the compressing/decompressing unit.

11. The test system according to claim 8, wherein the expected test pattern generated by the automatic test pattern generator is a scan test pattern.
